(19) United States
(12) Patent Application Publication
(10) Pub. No.: US 2026/0173353 A1
(43) Pub. Date: Jun. 18, 2026

(54) SEMICONDUCTOR MEMORY DEVICE

(71) Applicant: Samsung Electronics Co., Ltd., Suwon-si (KR)

(72) Inventors: Hyungki CHO, Suwon-si (KR); Gunjoo WOO, Suwon-si (KR); Sungwon YOO, Suwon-si (KR)

(21) Appl. No.: 19/335,348

(22) Filed: Sep. 22, 2025

(30) Foreign Application Priority Data
Dec. 17, 2024 (KR) 10-2024-0188217

(51) Int. Cl. H10B 12/00

(52) U.S. Cl. CPC H10B 12/33; H10B 12/05

(57) ABSTRACT

A semiconductor memory device include a conductive pad on an information storage structure, a channel structure on the conductive pad and including a vertical portion extending in a first direction, a word line extending in a second direction and on a plurality of side surfaces of the vertical portion, and a bit line on the channel structure and extending in a third direction intersecting with the second direction.

### CROSS-REFERENCE TO RELATED APPLICATION

This application claims priority to Korean Patent Application No. 10-2024-0188217, filed in the Korean Intellectual Property Office on Dec. 17, 2024, the entire contents of which are hereby incorporated by reference.

### TECHNICAL FIELD

The present disclosure relates to a semiconductor memory device.

### BACKGROUND

A semiconductor device may be a core component used in an electronic device to control or amplify an electrical signal, and various types of semiconductor devices may be manufactured. For example, a memory device may be used to store and retrieve data, while a non-memory device may be used to control or amplify the electrical signal. The semiconductor device may have an important role in various fields including computers, communication equipment, consumer electronics, etc.

As technology develops, performance and functional requirements of electronic devices are increasing. Accordingly, high-performance requirements of semiconductor devices are increasing, and the integration density of semiconductor devices is increasing to meet demand. Accordingly, a transistor with a vertical channel has been proposed to improve the integration density of semiconductor devices.

### SUMMARY

The present disclosure provides a semiconductor memory device with improved electrical characteristics and reliability.

According to some embodiments of the present disclosure, by arranging the word lines to surround a plurality of side surfaces of the vertical portion of the channel structure, the area of the word lines on the channel structure may be increased. As a result, the electrical characteristics and reliability of the semiconductor memory device may be improved.

According to some embodiments of the present disclosure, a semiconductor memory device may include, a conductive pad on an information storage structure, a channel structure on the conductive pad and including a vertical portion extending in a first direction, a word line extending in a second direction and on a plurality of side surfaces of the vertical portion, wherein the second direction is substantially perpendicular to the first direction, and a bit line on the channel structure and extending in a third direction intersecting with the second direction, wherein the third direction is substantially perpendicular to the first direction.

According to some embodiments of the present disclosure, a semiconductor memory device may include, first and second conductive pads on an information storage structure, respectively, a first channel structure on the first conductive pad and extending in a first direction, a second channel structure on the second conductive pad and extending in the first direction, a first word line extending in a second direction and on one side of the first channel structure, wherein the second direction is substantially perpendicular to the first direction, a second word line extending in the second direction, spaced apart from the first word line in a third direction intersecting with the first direction and substantially perpendicular to the first direction, and on one side of the second channel structure, a mold pattern between the first word line and the second word line, a liner insulating film between the first word line and the first channel structure and between the second word line and the second channel structure, and a bit line extending in the third direction and on a surface of the first channel structure opposite the first conductive pad and a surface of the second channel structure opposite the second conductive pad, wherein the first word line is adjacent to at least a portion of a side surface of the first channel structure, and the second word line is adjacent to at least a portion of a side surface of the second channel structure.

According to some embodiments of the present disclosure, a semiconductor memory device may include, first and second conductive pads on respective information storage structures, a lower insulating film on the first conductive pad and the second conductive pad, a first channel structure including a first horizontal portion on the first conductive pad and extending in a first direction, and a first vertical portion extending in a second direction on the first horizontal portion, wherein the second direction is substantially perpendicular to the first direction, a second channel structure including a second horizontal portion disposed on the second conductive pad and extending in the first direction, and a second vertical portion extending in the second direction on the second horizontal portion, a first word line extending in a third direction intersecting with the first direction and on one side of the first vertical portion, a second word line extending in the third direction and on one side of the second vertical portion, a mold pattern between the first word line and the second word line, a liner insulating film between the first word line and the first channel structure and between the second word line and the second channel structure, and a bit line extending in the first direction and on a surface of the first channel structure opposite the first conductive pad and a surface of the second channel structure opposite the second conductive pad, wherein the first word line is on a first side surface, a second side surface, and a third side surface of the first vertical portion, and the first side surface and the third side surface of the first vertical portion oppose each other in the third direction and are each connected to the second side surface.

### BRIEF DESCRIPTION OF THE DRAWINGS

The above and other embodiments and features of the present disclosure will become more apparent by describing in detail example embodiments thereof with reference to the attached drawings, in which:

FIG. 1 is a plan view illustrating a semiconductor memory device according to some embodiments;

FIG. 2 is an enlarged view illustrating a region Q1 of FIG. 1;

FIG. 3 is a cross-sectional view taken along line A-A of FIG. 1;

FIG. 4 is a cross-sectional view taken along line B-B of FIG. 1;

FIG. 5 is a cross-sectional view taken along line C-C of FIG. 1;

FIG. 6 is a diagram illustrating the semiconductor memory device according to some embodiments;

FIG. 7 is a diagram illustrating a semiconductor memory device according to some embodiments.

FIG. 8 is a diagram illustrating a semiconductor memory device according to some embodiments;

FIG. 9 is a diagram illustrating a semiconductor memory device according to some embodiments;

FIG. 10 is a diagram illustrating a semiconductor memory device according to some embodiments;

FIG. 11 is a plan view illustrating a method for manufacturing the semiconductor memory device according to some embodiments;

FIG. 12 is a cross-sectional view taken along line A-A of FIG. 11;

FIG. 13 is a plan view illustrating a method for manufacturing the semiconductor memory device according to some embodiments;

FIG. 14 is a cross-sectional view taken along line A-A of FIG. 13;

FIG. 15 is a plan view illustrating a method for manufacturing a semiconductor memory device according to some embodiments;

FIGS. 16 and 17 are cross-sectional views taken along line A-A and line B-B of FIG. 15;

FIG. 18 is a plan view illustrating a method for manufacturing a semiconductor memory device according to some embodiments;

FIGS. 19 and 20 are cross-sectional views taken along line A-A and line B-B of FIG. 18;

FIG. 21 is a plan view illustrating a method for manufacturing a semiconductor memory device according to some embodiments;

FIGS. 22 and 23 are cross-sectional views taken along line A-A and line B-B of FIG. 21;

FIG. 24 is a plan view illustrating a method for manufacturing a semiconductor memory device according to some embodiments;

FIGS. 25 and 26 are cross-sectional views taken along line A-A and line B-B of FIG. 24;

FIG. 27 is a plan view illustrating a method for manufacturing a semiconductor memory device according to some embodiments;

FIGS. 28 and 29 are cross-sectional views taken along line A-A and line B-B of FIG. 27;

FIG. 30 is a plan view illustrating a method for manufacturing a semiconductor memory device according to some embodiments;

FIGS. 31 and 32 are cross-sectional views taken along line A-A and line B-B of FIG. 30;

FIG. 33 is a plan view illustrating a method for manufacturing a semiconductor memory device according to some embodiments;

FIGS. 34 and 35 are cross-sectional views taken along line A-A and line B-B of FIG. 33;

FIGS. 36 and 37 are diagrams illustrating a method for manufacturing a semiconductor memory device according to some embodiments;

FIG. 38 is a plan view illustrating a method for manufacturing a semiconductor memory device according to some embodiments;

FIG. 39 is a cross-sectional view taken along line B-B in FIG. 38;

FIGS. 40 and 41 are diagrams illustrating a method for manufacturing a semiconductor memory device according to some embodiments.

### DETAILED DESCRIPTION

Hereinafter, a semiconductor memory device and a method for manufacturing the semiconductor memory device according to some embodiments of the present disclosure will be described in detail with reference to the drawings.

The terms “first,” “second,” etc., may be used herein merely to distinguish one component, layer, direction, etc. from another. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present. Likewise, when components are “immediately” adjacent to one another, no intervening components may be present.

The term “surrounding” or “covering” or “filling” as may be used herein may not require completely surrounding or covering or filling the described elements or layers, but may, for example, refer to partially surrounding or covering or filling the described elements or layers, for example, with voids, spaces, or other discontinuities throughout. The term “exposed,” may be used to describe relationships between elements and/or certain intermediate processes in fabricating a completed semiconductor device, but may not necessarily require exposure of the particular region, layer, structure or other element in the context of the completed device.

It will be understood that spatially relative terms such as “above,” “upper,” “upper portion,” “upper surface,” “below,” “lower,” “lower portion,” “lower surface,” “side surface,” and the like may be denoted by reference numerals and refer to the drawings, except where otherwise indicated. It will be understood that such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

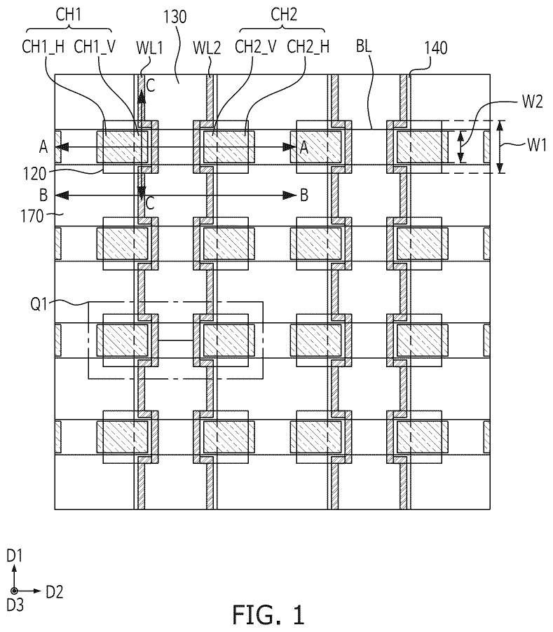

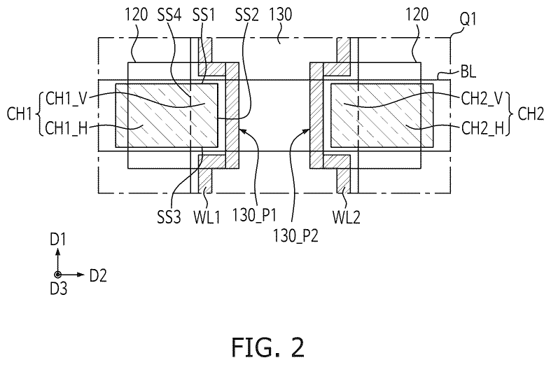

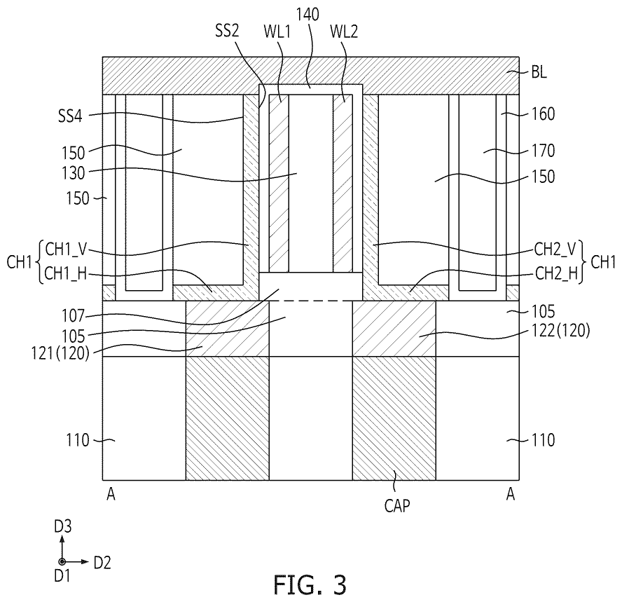

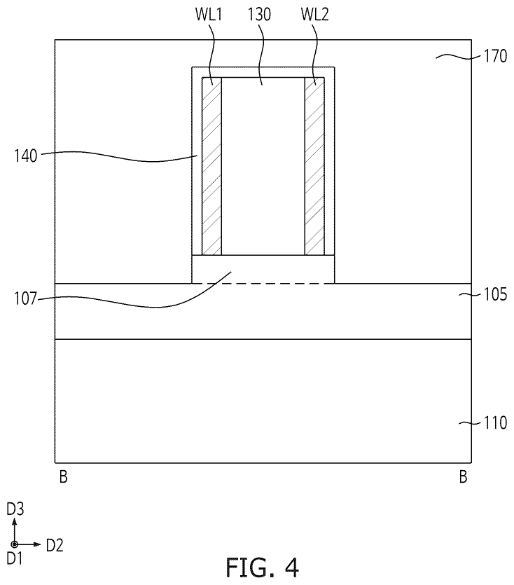

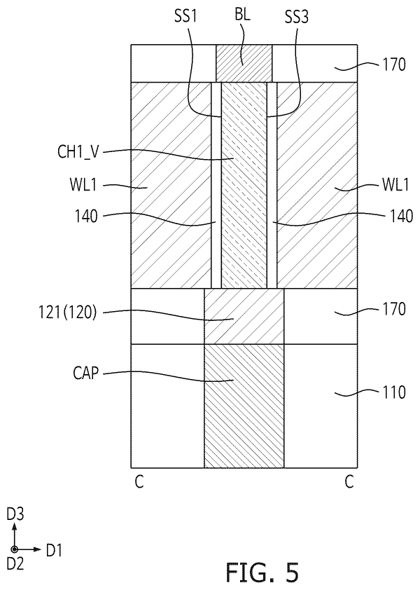

FIG. 1 is a plan view illustrating a semiconductor memory device according to some embodiments. FIG. 2 is an enlarged view illustrating a region Q1 of FIG. 1. FIG. 3 is a cross-sectional view taken along line A-A of FIG. 1. FIG. 4 is a cross-sectional view taken along line B-B of FIG. 1. FIG. 5 is a cross-sectional view taken along line C-C of FIG. 1. For reference, in FIG. 1, illustrations of an information storage structure CAP and an interlayer insulating film 170 are omitted.

The semiconductor memory device according to some embodiments may include memory cells including a vertical channel transistor (VCT). The vertical channel transistor may refer to a transistor with a channel length extending in a vertical direction.

Referring to FIGS. 1 to 5, the semiconductor memory device according to some embodiments may include a first lower insulating film 110, a second lower insulating film 105, a protruding insulating film 107, a conductive pad 120, the information storage structure CAP, a mold pattern 130, a first word line WL1, a second word line WL2, a liner insulating film 140, a first channel structure CH1, a second channel structure CH2, an upper insulating film 150, an isolation liner film 160, the interlayer insulating film 170, and a bit line BL.

The information storage structures CAP may be disposed to be spaced apart from each other in a first direction D1 and a second direction D2. The first lower insulating film 110 may be disposed between the information storage structure CAP and adjacent information storage structure CAP. The information storage structure CAP may be disposed below the conductive pad 120. Although the information storage structure CAP is illustrated as a single film, embodiments are not limited thereto. The information storage structure CAP may include, for example, a first electrode, a dielectric film, and a second electrode.

The information storage structure CAP may be electrically connected to the conductive pad 120. The information storage structure CAP may store a signal received from a transistor in a peripheral circuit structure (e.g., row and column decoders, sense amplifier, etc.) of the semiconductor memory device. The information storage structure CAP may be used as an information storage element electrically connected to the transistor. For example, the information storage structure CAP may store charges under the control of the transistor.

The first lower insulating film 110 may surround each of a plurality of information storage structures CAP. For example, the first lower insulating film 110 may be disposed between the information storage structures CAP. The first lower insulating film 110 may overlap with the information storage structure CAP in the first direction D1 and the second direction D2. Components or layers described with reference to “overlap” in a particular direction may be at least partially obstructed by one another when viewed along a line extending in the particular direction or in a plane perpendicular to the particular direction.

For example, the first lower insulating film 110 may include at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof. However, embodiments are not limited to the above.

The first direction D1 may be a direction intersecting with the second direction D2. For example, the first direction D1 may be a direction perpendicular to the second direction D2. A third direction D3 may be a direction perpendicular to each of the first and second directions D1 and D2. In other words, the first and second directions D1 and D2 may be horizontal, and the third direction D3 may be vertical.

The conductive pad 120 may be disposed on the information storage structure CAP. For example, corresponding conductive pads 120 may be disposed on each of the plurality of information storage structures CAP. A plurality of conductive pads 120 may be disposed to be spaced apart from each other in the first and second directions D1 and D2. In some embodiments, an upper surface of the conductive pad 120 may be disposed on the same plane as an upper surface of the second lower insulating film 105. However, embodiments are not limited to the above.

Although the conductive pad 120 in a rectangular shape is illustrated from a planar perspective, embodiments are not limited thereto. The conductive pad 120 may have various shapes such as a circle, an ellipse, a rhombus, and a hexagon in a plan view, for example.

The conductive pad 120 may be formed of a doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but embodiments are not limited thereto.

The second lower insulating film 105 may surround the conductive pad 120. The second lower insulating film 105 may overlap with the conductive pad 120 in the first and second directions D1 and D2. For example, the second lower insulating film 105 may include any one of silicon nitride (SiN), silicon oxynitride (SiON), silicon carbonitride (SiCN), and silicon oxycarbonitride (SiOCN). However, embodiments are not limited to the above.

The plurality of conductive pads 120 may include a first conductive pad 121 and a second conductive pad 122. The first conductive pad 121 may be spaced apart from the second conductive pad 122 in the second direction D2. The first channel structure CH1 may be disposed on the first conductive pad 121. The second channel structure CH2 may be disposed on the second conductive pad 122.

The protruding insulating film 107 may be disposed on the first conductive pad 121, the second conductive pad 122, and the second lower insulating film 105. The protruding insulating film 107 may be disposed on a portion of the second lower insulating film 105 disposed between the first conductive pad 121 and the second conductive pad 122. The protruding insulating film 107 may overlap with a portion of an upper surface of the first conductive pad 121 and a portion of an upper surface of the second conductive pad 122 in the third direction D3.

The protruding insulating film 107 may extend in the first direction D1 on the second lower insulating film 105. In some embodiments, a width of the protruding insulating film 107 in the second direction D2 may not be constant. For example, the width of the protruding insulating film 107, disposed on the first and second conductive pads 121 and 122, in the second direction D2 may be less than the width of the protruding insulating film 107, not disposed on the first and second conductive pads 121 and 122, in the second direction D2. However, embodiments are not limited to the above. Unlike the illustration, the width of the protruding insulating film 107 in the second direction D2 may be constant.

In some embodiments, a boundary surface between the protruding insulating film 107 and the second lower insulating film 105 may not be distinguished. However, embodiments are not limited to the above. The protruding insulating film 107 may include an insulating material. The protruding insulating film 107 may include any one of, for example, silicon nitride, silicon oxynitride, silicon oxycarbonitride, and silicon carbonitride, but embodiments are not limited thereto.

The mold pattern 130 may be disposed on the protruding insulating film 107. The mold pattern 130 may extend in the first direction D1 along the protruding insulating film 107. The mold pattern 130 may be disposed between the first word line WL1 and the second word line WL2 which will be described below. The first word line WL1 and the second word line WL2 may be spaced apart from each other in the second direction D2 by the mold pattern 130.

In some embodiments, a width of the mold pattern 130 in the second direction D2 may not be constant. A width in the second direction D2 of a portion of the mold pattern 130 overlapping with the channel structures CH1 and CH2 in the second direction D2 may be less than a width of the remaining portion of the mold pattern 130 in the second direction D2.

For example, as illustrated in FIG. 2, the mold pattern 130 may include a first recessed part 130_P1 and a second recessed part 130_P2. The first recessed part 130_P1 may be disposed adjacent to the first channel structure CH1, and the second recessed part 130_P2 may be disposed adjacent to the second channel structure CH2. In other words, the first recessed part 130_P1 may overlap with the first channel structure CH1 in the second direction D2, and the second recessed part 130_P2 may overlap with the second channel structure CH2 in the second direction D2. Due to the shapes of the first recessed part 130_P1 and the second recessed part 130_P2, a width of the mold pattern 130 in the second direction D2 between the first recessed part 130_P1 and the second recessed part 130_P2 may be less than a width of the remaining portion.

Each of the first recessed part 130_P1 and the second recessed part 130_P2 of the mold pattern 130 may be aligned to be spaced apart in the first direction D1. That is, as illustrated in FIG. 1, from a planar perspective, the mold pattern 130 may be arranged such that a wide portion and a narrow portion in the second direction D2 may be alternately arranged in the first direction D1.

The width of the mold pattern 130 in the second direction D2 may be less than the width of the protruding insulating film 107 in the second direction D2. For example, the width of the mold pattern 130 in the second direction D2 may be less than the width of the protruding insulating film 107, disposed below the mold pattern 130, in the second direction D2.

Specifically, as illustrated in FIG. 3, a width of a portion of the mold pattern 130, disposed between the first channel structure CH1 and the second channel structure CH2, in the second direction D2 may be less than a width of a portion of the protruding insulating film 107, disposed between the first channel structure CH1 and the second channel structure CH2, in the second direction D2. In addition, as illustrated in FIG. 4, a width of a portion of the mold pattern 130, disposed in the interlayer insulating film 170, in the second direction D2 may be less than a width of a portion of the protruding insulating film 107, disposed in the interlayer insulating film 170, in the second direction D2.

The mold pattern 130 may include an insulating material. For example, the mold pattern 130 may include at least one of silicon oxide, silicon nitride, silicon oxynitride, and a low-k insulating material, but embodiments are not limited thereto.

The first word line WL1 may be disposed on an upper surface of the protruding insulating film 107. The first word line WL1 may be disposed on a side surface of the mold pattern 130. The first word line WL1 may extend in the first direction D1. For example, the first word line WL1 may extend in the first direction D1 along a first side surface of the mold pattern 130. The first side surface of the mold pattern 130 may include the first recessed part 130_P1. That is, the first word line WL1 may be disposed along the first recessed part 130_P1 of the mold pattern 130.

The second word line WL2 may be disposed on the upper surface of the protruding insulating film 107. The second word line WL2 may be disposed on the side surface of the mold pattern 130. The second word line WL2 may extend in the first direction D1. For example, the second word line WL2 may extend in the first direction D1 along a second side surface of the mold pattern 130. The second side surface of the mold pattern 130 may include the second recessed part 130_P2. That is, the second word line WL2 may be disposed along the second recessed part 130_P2 of the mold pattern 130.

The first word line WL1 may be disposed to be spaced apart from the second word line WL2 in the second direction D2. The mold pattern 130 may be disposed between the first word line WL1 and the second word line WL2. The first word line WL1 and the second word line WL2 may be symmetrical to each other, with the mold pattern 130 interposed therebetween.

In some embodiments, an upper surface of the first word line WL1, an upper surface of the second word line WL2, and an upper surface of the mold pattern 130 may be disposed on the same plane. The upper surface of the first word line WL1, the upper surface of the second word line WL2, and the upper surface of the mold pattern 130 may be disposed at the same vertical level. In other words, a distance from the upper surface of the conductive pad 120 to the upper surface of the first word line WL1, a distance to the upper surface of the second word line WL2, and a distance to the upper surface of the mold pattern 130 may all be the same. However, embodiments are not limited to the above.

For example, each of the first word line WL1 and the second word line WL2 may include at least one of doped polysilicon, metal (e.g., Al, Cu, Ti, Ta, Ru, W, Mo, Pt, Ni, Co), conductive metal nitride (e.g., TiN, TaN, WN, NbN, TiAlN, TiSiN, TaSiN, RuTiN), conductive metal silicide or conductive metal oxide (e.g., PtO, RuO₂, IrO₂, SrRuO₃(SRO), (Ba,Sr)RuO₃(BSRO), CaRuO₃(CRO), LSCo), but embodiments are not limited thereto. The word line WL may include a single layer of each of the materials described above or multiple layers of the materials.

In some embodiments, each of the first word line WL1 and the second word line WL2 may include a two-dimensional semiconductor material. For example, the 2D semiconductor material may include graphene, carbon nanotube, or a combination thereof, but embodiments are not limited thereto.

The liner insulating film 140 may be disposed on the first word line WL1, the second word line WL2, and the mold pattern 130. For example, the liner insulating film 140 may be disposed between the first word line WL1 and the first channel structure CH1. The liner insulating film 140 may be disposed between the second word line WL2 and the second channel structure CH2. The liner insulating film 140 may be disposed between the bit line BL and the first word line WL1 and between the bit line BL and the second word line WL2. The liner insulating film 140 may extend in the first direction D1 along side surfaces of the first word line WL1 and the second word line WL2.

In some embodiments, a thickness of the liner insulating film 140 may not be constant. For example, a thickness of a portion of the liner insulating film 140 disposed between the first word line WL1 and the first channel structure CH1 may be different from a thickness of a portion of the liner insulating film 140 disposed below the bit line BL. However, embodiments are not limited to the above.

The liner insulating film 140 may include at least one of silicon oxide, silicon oxynitride, and a high-k material with a higher dielectric constant than silicon oxide. The high-k material may include a metal oxide or a metal oxynitride. For example, the high-k material of the liner insulating film 140 may include at least one of HfO₂, HfSiO, HfSiON, HfTaO, HfTiO, HfZrO, ZrO₂ and Al₂O₃, but embodiments are not limited thereto.

The first channel structure CH1 may be disposed on the first conductive pad 121. The first channel structure CH1 may be connected to the first conductive pad 121. The first channel structure CH1 may be disposed on one side of the first word line WL1. The first channel structure CH1 may extend in the third direction D3. In some embodiments, the first channel structure CH1 may be in contact with a side surface of the protruding insulating film 107. However, embodiments are not limited to the above.

The first channel structure CH1 may include a first horizontal portion CH1_H and a first vertical portion CH1_V. The first horizontal portion CH1_H may be disposed on the first conductive pad 121 and the second lower insulating film 105. The first horizontal portion CH1_H may extend in the second direction D2. The first horizontal portion CH1_H may cover a portion of the upper surface of the first conductive pad 121. The first horizontal portion CH1_H may overlap with a portion of the first conductive pad 121 in the third direction D3. The first horizontal portion CH1_H may be connected to the first conductive pad 121.

The first vertical portion CH1_V may extend in the third direction D3 on the first horizontal portion CH1_H. The first vertical portion CH1_V may extend in the third direction D3 along the liner insulating film 140. From a planar perspective, the first vertical portion CH1_V may include a rectangular shape.

The first vertical portion CH1_V may have a plurality of side surfaces. The first vertical portion CH1_V may include first to fourth side surfaces SS1, SS2, SS3, and SS4. The first side surface SS1 may face the third side surface SS3 in the first direction D1. The second side surface SS2 may face the fourth side surface SS4 in the second direction D2. Hence, opposite or opposing sides of the vertical portion CH1_V may be described as facing one another. The first side surface SS1 and the third side surface SS3 may be connected to the second side surface SS2 and the fourth side surface SS4, respectively.

As illustrated in FIG. 3, the first word line WL1 may be disposed on the second side surface SS2 with the liner insulating film 140 therebetween. The second side surface SS2 may face the first word line WL1. For example, the second side surface SS2 may overlap with the first word line WL1 in the second direction D2. As illustrated in FIG. 5, the first word line WL1 may be disposed on each of the first side surface SS1 and the third side surface SS3. Each of the first side surface SS1 and the third side surface SS3 may face the first word line WL1. For example, each of the first side surface SS1 and the third side surface SS3 may overlap with the first word line WL1 in the first direction D1.

The first word line WL1 may be disposed on a plurality of side surfaces of the first vertical portion CH1_V. In some embodiments, the first word line WL1 may be disposed to surround the plurality of side surfaces of the first vertical portion CH1_V. The phrase ‘surrounding a plurality of side surfaces’ may include being disposed on two or more side surfaces. In addition, when the first word line WL1 is disposed on a side surface of a component, it may include the first word line WL1 being disposed on or overlapped with all or part of the side surface. For example, the first word line WL1 may overlap with portions of the first and third side surfaces SS1 and SS3 of the first vertical portion CH1_V in the first direction D1.

The first word line WL1 may include an extended part extending in the first direction D1 and a recessed part disposed on the first vertical portion CH1_V of the first channel structure CH1. The recessed part of the first word line WL1 may be disposed on the first recessed part 130_P1 of the mold pattern 130. The recessed part of the first word line WL1 may surround or be adjacent to a plurality of side surfaces of the first vertical portion CH1_V. The recessed part of the first word line WL1 may be disposed on the first side surface SS1, the second side surface SS2, and the third side surface SS3 of the first vertical portion CH1_V.

The second channel structure CH2 may be spaced apart from the first channel structure CH1 in the second direction D2. The liner insulating film 140, the first word line WL1, the mold pattern 130, and the second word line WL2 may be disposed between the first channel structure CH1 and the second channel structure CH2. In addition, the protruding insulating film 107 may be disposed between the first channel structure CH1 and the second channel structure CH2. However, embodiments are not limited to the above. For example, the protruding insulating film 107 may be omitted. The first channel structure CH1 and the second channel structure CH2 may be symmetrical to each other, with the mold pattern 130 interposed therebetween.

The second channel structure CH2 may be disposed on the second conductive pad 122. The second channel structure CH2 may be connected to the second conductive pad 122. The second channel structure CH2 may be disposed on one side of the second word line WL2. The second channel structure CH2 may extend in the third direction D3. In some embodiments, the second channel structure CH2 may be in contact with the side surface of the protruding insulating film 107. However, embodiments are not limited to the above.

The second channel structure CH2 may include a second horizontal portion CH2_H and a second vertical portion CH2_V. The second horizontal portion CH2_H may be disposed on the second conductive pad 122 and the second lower insulating film 105. The second horizontal portion CH2_H may extend in the second direction D2. The second horizontal portion CH2_H may cover a portion of the upper surface of the second conductive pad 122. The second horizontal portion CH2_H may overlap with a portion of the second conductive pad 122 in the third direction D3. The second horizontal portion CH2_H may be connected to the second conductive pad 122.

The second vertical portion CH2_V may extend in the third direction D3 on the second horizontal portion CH2_H. The second vertical portion CH2_V may extend in the third direction D3 along the liner insulating film 140. From a planar perspective, the second vertical portion CH2_V may include a rectangular shape.

The second vertical portion CH2_V may include a plurality of side surfaces. The second vertical portion CH2_V may include fifth to eighth side surfaces. The fifth side surface may face the seventh side surface in the first direction D1. The sixth side surface may face the eighth side surface in the second direction D2. The fifth and seventh side surfaces may be connected to each of the sixth and eighth side surfaces.

Description of each of the fifth to eighth side surfaces of the second vertical portion CH2_V may be similar to the description of the first to fourth side surfaces SS1, SS2, SS3 and SS4 of the first vertical portion CH1_V. For example, description of a relationship between each of the fifth to eighth side surfaces of the second vertical portion CH2_V and the second word line WL2 may be similar to the description of the relationship between the first to fourth side surfaces SS1, SS2, SS3, and SS4 of the first vertical portion CH1_V and the first word line WL1.

For example, the fifth and seventh side surfaces of the second vertical portion CH2_V may face the second word line WL2 and overlap with the second word line WL2 in the first direction D1. A sixth side surface of the second vertical portion CH2_V may face the second word line WL2, and may overlap with the second word line WL2 in the second direction D2.

The second word line WL2 may be disposed on a plurality of side surfaces of the second vertical portion CH2_V. In some embodiments, the second word line WL2 may be disposed to surround a plurality of side surfaces of the second vertical portion CH2_V. The phrase ‘surrounding a plurality of side surfaces’ may include being disposed on two or more side surfaces. In addition, when the second word line WL2 is disposed on a side surface of a component, it may include the first word line WL1 being disposed on or overlapped with all or part of the side surface. For example, the second word line WL2 may overlap with portions of the fifth and seventh side surfaces of the second vertical portion CH2_V in the first direction D1.

The second word line WL2 may include an extended part extending in the first direction D1 and a recessed part disposed on the second vertical portion CH2_V of the second channel structure CH2. The recessed part of the second word line WL2 may be disposed on the second recessed part 130_P2 of the mold pattern 130. The recessed part of the second word line WL2 may surround a plurality of side surfaces of the second vertical portion CH2_V. The recessed part of the second word line WL2 may be disposed on the fifth, sixth, and seventh side surfaces of the second vertical portion CH2_V.

In the semiconductor memory device according to some embodiments, with the word lines WL1 and WL2 disposed to surround a plurality of side surfaces of the vertical portions CH1_V and CH2_V of the channel structures CH1 and CH2, the area of the word lines WL1 and WL2 disposed on the channel structures CH1 and CH2 may increase. For example, compared to the word line disposed only on one side surface of the vertical portion of the channel structure, the first word line WL1 according to some embodiments may be disposed on the first side surface SS1, the second side surface SS2, and the third side surface SS3 of the first vertical portion CH1_V1. Accordingly, the electrical characteristics of the transistors using the first word line WL1 as a gate electrode and using the first channel structure CH1 as a channel region may be improved. In addition, the reliability of a semiconductor memory device including the same may be enhanced.

Each of the first channel structure CH1 and the second channel structure CH2 may include an oxide semiconductor. For example, the oxide semiconductor may include at least one of InₓGa_{y}Zn_{z}O, InₓGa_{y}Si_{z}O, InₓSn_{y}Zn_{z}O, InₓZn_{y}O, ZnₓO, ZnₓSn_{y}O, ZnₓO_{y}N, ZrₓZn_{y}Sn_{z}O, SnₓO, HfₓIn_{y}Zn_{z}O, GaₓZn_{y}Sn_{z}O, AlₓZn_{y}Sn_{z}O, YbₓGa_{y}Zn_{z}O and InₓGa_{y}O, but embodiments are not limited thereto. For example, the channel structure CH may include an indium gallium zinc oxide (IGZO). The channel structure CH may include a single layer or multiple layers of an oxide semiconductor. The channel structure CH may include an amorphous, crystalline, or polycrystalline oxide semiconductor.

In some embodiments, each of the first channel structure CH1 and the second channel structure CH2 may have a band gap energy greater than that of silicon. For example, the channel structure CH may have a band gap energy of about 1.5 eV to 5.6 eV. For example, the channel structure CH may have optimal channel performance when it has a band gap energy of about 2.0 eV to 4.0 eV. For example, the channel structure CH may be polycrystalline or amorphous, but embodiments are not limited thereto.

In some embodiments, each of the first channel structure CH1 and the second channel structure CH2 may include a 2D semiconductor material. For example, the 2D semiconductor material may include graphene, carbon nanotube, or a combination thereof.

In some embodiments, a width W2 of the channel structures CH1 and CH2 in the first direction D1 may be less than a width W1 of the conductive pad 120 in the first direction D1. For example, the width W2 of the first channel structure CH1 in the first direction D1 may be less than the width W1 of the first conductive pad 121 in the first direction D1, and the width W2 of the second channel structure CH2 in the first direction D1 may be less than the width W1 of the second conductive pad 122 in the first direction D1.

The upper insulating film 150 may be disposed on the first channel structure CH1 and the second channel structure CH2. For example, the upper insulating film 150 may be disposed on an upper surface of the first horizontal portion CH1_H and on the fourth side surface SS4 of the first vertical portion CH1_V. The upper insulating film 150 may be disposed between the first horizontal portion CH1_H and the bit line BL. The upper insulating film 150 may be disposed on an upper surface of the second horizontal portion CH2_H and on the eighth side surface of the second vertical portion CH2_V. The upper insulating film 150 may be disposed between the second horizontal portion CH2_H and the bit line BL. Although it is illustrated that an upper surface of the upper insulating film 150, an upper surface of the first vertical portion CH1_V, and an upper surface of the second vertical portion CH2_V are disposed at the same vertical level, embodiments are not limited thereto.

The isolation liner film 160 may be disposed on the second lower insulating film 105. The isolation liner film 160 may be disposed on the upper insulating film 150. The isolation liner film 160 may be disposed between the upper insulating film 150 and an adjacent upper insulating film 150 in the second direction D2. The isolation liner film 160 may extend along a side surface of the upper insulating film 150. The isolation liner film 160 may be in contact with the horizontal portions CH1_H and CH2_H of the channel structures CH1 and CH2. From a cross-sectional perspective, the isolation liner film 160 may have a “U”-like shape.

The interlayer insulating film 170 may be disposed in the isolation liner film 160. For example, the interlayer insulating film 170 may fill a space in the isolation liner film 160. The interlayer insulating film 170 may be disposed on the second lower insulating film 105 and the liner insulating film 140. For example, as illustrated in FIG. 4, in a region where the bit line BL is not disposed, the interlayer insulating film 170 may cover the second lower insulating film 105 and the liner insulating film 140.

For example, the interlayer insulating film 170 may include at least one of silicon oxide, silicon oxynitride, and a low-k material having a lower dielectric constant than silicon oxide, but embodiments are not limited thereto.

The bit line BL may extend in the second direction D2. The bit line BL may intersect with the word lines WL1 and WL2. The bit line BL may be disposed on the channel structures CH1 and CH2. The bit line BL may be connected to the channel structures CH1 and CH2. The bit line BL may be disposed to be spaced apart from the word lines WL1 and WL2. For example, due to the liner insulating film 140, contact of the bit line BL with the word lines WL1 and WL2 may be prevented.

The bit line BL may include a conductive material. For example, the bit line may include at least one of doped polysilicon, metal (e.g., Al, Cu, Ti, Ta, Ru, W, Mo, Pt, Ni, Co), conductive metal nitride (e.g., TiN, TaN, WN, NbN, TiAlN, TiSiN, TaSiN, RuTiN), conductive metal silicide or conductive metal oxide (e.g., PtO, RuO₂, IrO₂, SrRuO₃(SRO), (Ba,Sr)RuO₃(BSRO), CaRuO₃(CRO), LSCo), and a two-dimensional (2D) material, but embodiments are not limited thereto.

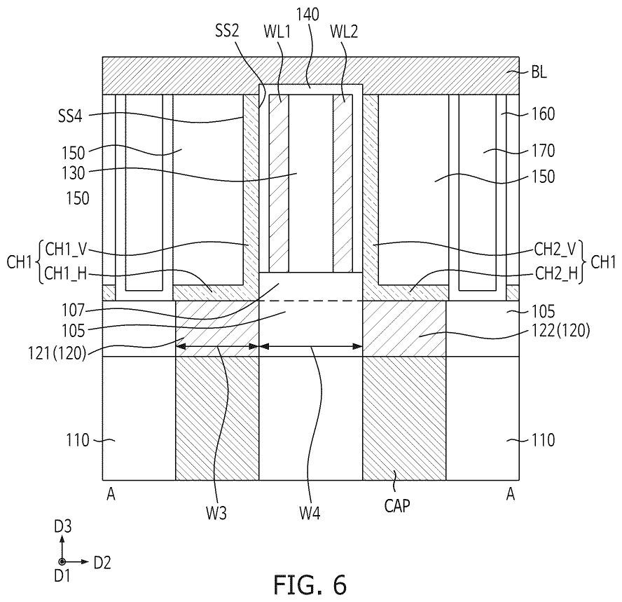

FIG. 6 is a diagram illustrating the semiconductor memory device according to some embodiments. For reference, FIG. 6 may correspond to a cross-sectional view taken along line A-A of FIG. 1. For convenience of explanation, different configurations from those described in FIGS. 1 to 5 will be mainly described.

Referring to FIG. 6, in the semiconductor memory device according to some embodiments, a distance W4 between the first conductive pad 121 and the second conductive pad 122 may be different from a width of the first conductive pad 121 in the second direction D2.

Each of the first conductive pad 121 and the second conductive pad 122 may have a third width W3 in the second direction D2. The distance W4 between the first conductive pad 121 and the second conductive pad 122 spaced apart from the first conductive pad 121 in the second direction D2 may be greater than the third width W3.

In some embodiments, the distance W4 between the first conductive pad 121 and the second conductive pad 122 spaced apart from the first conductive pad 121 in the second direction D2 may be the same as the width of the protruding insulating film 107 in the second direction D2. Accordingly, an overlapped area between the first horizontal portion CH1_H of the first channel structure CH1 and the first conductive pad 121 in the third direction D3 may increase. In addition, an overlapped area between the second horizontal portion CH2_H of the second channel structure CH2 and the second conductive pad 122 in the third direction D3 may increase. That is, contact resistance between the conductive pad 120 and the channel structures CH1 and CH2 may be reduced.

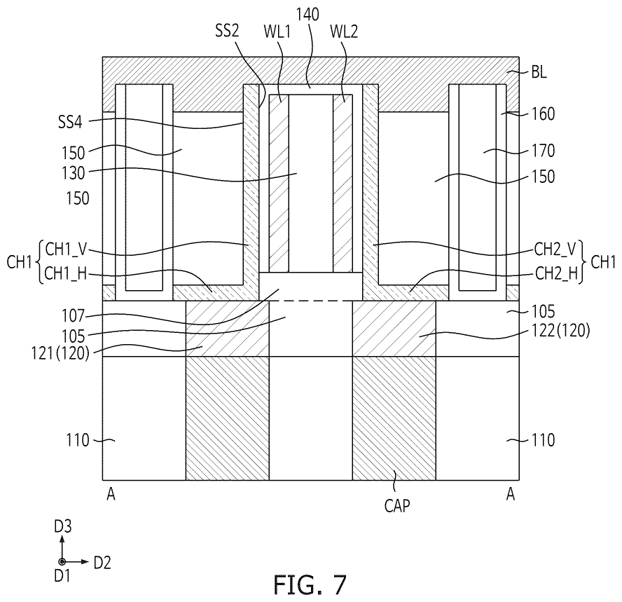

FIG. 7 is a diagram illustrating a semiconductor memory device according to some embodiments. For reference, FIG. 7 may correspond to a cross-sectional view taken along line A-A of FIG. 1. For convenience of explanation, different configurations from those described in FIGS. 1 to 5 will be mainly described.

Referring to FIG. 7, in the semiconductor memory device according to some embodiments, a lower surface of the bit line BL may be disposed at a vertical level different from upper surface of the channel structures CH1 and CH2.

A portion of the bit line BL may be disposed between the first channel structure CH1 and the isolation liner film 160 and between the second channel structure CH2 and the isolation liner film 160. For example, the lower surface of the bit line BL may be disposed between the first channel structure CH1 and the isolation liner film 160 and between the second channel structure CH2 and the isolation liner film 160. The lower surface of the bit line BL may be a surface that is in contact with the upper surface of the upper insulating film 150.

The lower surface of the bit line BL may be disposed at a vertical level lower than the upper surface of the first vertical portion CH1_V. The bit line BL may be disposed on the upper surface of the first vertical portion CH1_V and on a portion of the fourth side surface SS4. The lower surface of the bit line BL may be disposed at a vertical level lower than the upper surface of the second vertical portion CH2_V. The bit line BL may be disposed on the upper surface of the second vertical portion CH2_V and on a portion of the eighth side surface. The upper surface of the first vertical portion CH1_V may be a surface of the first vertical portion CH1_V opposite the first conductive pad 121. The upper surface of the second vertical portion CH2_V may be a surface of the second vertical portion CH2_V opposite the second conductive pad 122. With the bit line BL in contact with the portions of the upper and side surfaces of the channel structures CH1 and CH2, a contact area between the bit line BL and the channel structures CH1 and CH2 may increase, thereby reducing resistance.

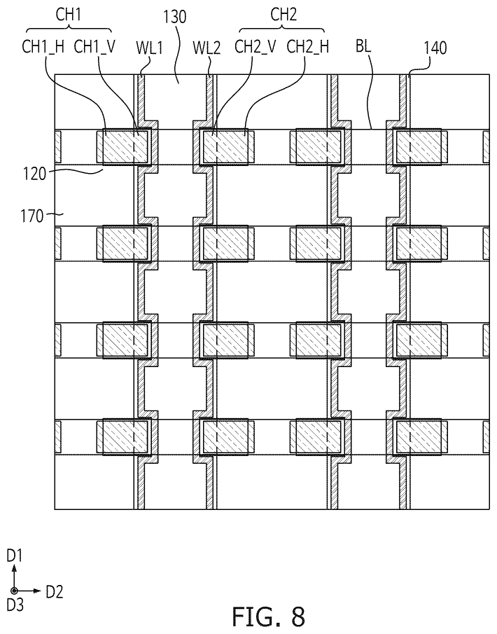

FIG. 8 is a diagram illustrating a semiconductor memory device according to some embodiments. For convenience of explanation, different configurations from those described in FIGS. 1 to 5 will be mainly described.

Referring to FIG. 8, in the semiconductor memory device according to some embodiments, a width of the conductive pad 120 in the first direction D1 may be different from a width of the recessed part of the first word line WL1 in the first direction D1.

The recessed part of the first word line WL1 may surround a plurality of side surfaces of the first vertical portion CH1_V of the first channel structure CH1. The width of the recessed part of the first word line WL1 in the first direction D1 may correspond to a distance between outer surfaces of the first word line WL1 in the first direction D1 on the recessed part of the first word line WL1. The width of the first conductive pad 121 in the first direction D1 may be less than the width of the recessed part of the first word line WL1 in the first direction D1. Accordingly, the first conductive pad 121 and the first word line WL1 may not overlap with each other in the third direction D3. Likewise, the second conductive pad 122 and the second word line WL2 may not overlap with each other in the third direction D3.

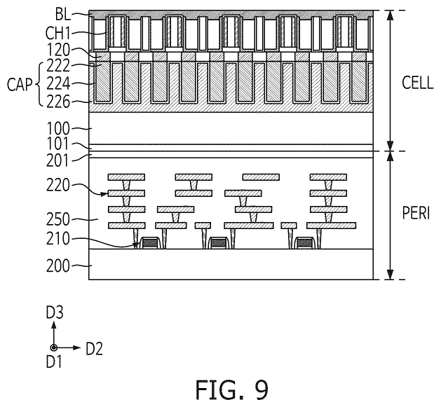

FIG. 9 is a diagram illustrating a semiconductor memory device according to some embodiments. For convenience of description, different configurations from those described in FIGS. 1 to 8 will be mainly described.

Referring to FIG. 9, the semiconductor memory device according to some embodiments may include a cell structure CELL and a peripheral circuit structure PERI.

The cell structure CELL may include an insulating substrate 100 and a first bonding insulating layer 101 disposed on the semiconductor memory device and information storage structure CAP described with reference to FIGS. 1 to 8.

The information storage structure CAP may include a first electrode 222, a dielectric film 224, and a second electrode 226. The first electrode 222 may be disposed on the conductive pad 120. The first electrode 222 may be electrically connected to the conductive pad 120.

For example, the first electrode 222 may include at least one of a conductive metal material (cobalt (Co), titanium (Ti), nickel (Ni), tungsten (W), molybdenum (Mo), etc.), a metal nitride (titanium nitride (TiN), titanium silicon nitride (TiSiN), titanium aluminum nitride (TiAlN), tantalum aluminum nitride (TaAlN), tungsten nitride (WN), etc.), a precious metal material (platinum (Pt), ruthenium (Ru), iridium (Ir), etc.), a conductive oxide film (PtO, RuO₂, IrO₂, SRO(SrRuO₃), BSRO((Ba,Sr)RuO₃), CRO(CaRuO₃), LSCo, etc.), and a metal silicide film. However, embodiments are not limited to the above.

The dielectric film 224 may be disposed on the first electrode 222. The dielectric film 224 may extend along a profile of the first electrode 222. For example, the dielectric film 224 may include a high-k material including a silicon oxide, a silicon nitride, a silicon oxynitride, and a metal. Although it is illustrated that the dielectric film 224 is a single film, it is only for convenience of description, and embodiments are not limited thereto. Unlike the illustration, the dielectric film 224 may include a plurality of films.

The second electrode 226 may be disposed on the dielectric film 224. The second electrode 226 may fill an empty space between the first electrodes 222. The second electrode 226 may include at least one of, for example, an elemental semiconductor material film and a compound semiconductor material film. The second electrode 226 may include a doped n-type impurity or a p-type impurity.

The insulating substrate 100 may be disposed below the information storage structure CAP. The insulating substrate 100 may be disposed on a lower surface of the second electrode 226. The insulating substrate 100 may include an insulating material. The first bonding insulating layer 101 may be disposed on a lower surface of the insulating substrate 100.

The peripheral circuit structure PERI may include a substrate 200, a plurality of peripheral circuit transistors 210, a wiring structure 220, a peripheral circuit insulating film 250, and a second bonding insulating layer 201.

The substrate 200 may be a semiconductor substrate. For example, the substrate 200 may include silicon (Si), silicon germanium (SiGe), indium antimonide (InSb), lead telluride (PbTe), indium arsenide (InAs), indium phosphide (INP), gallium arsenide (GaAs), gallium antimonide (GaSb), etc. However, embodiments are not limited to the above.

The plurality of peripheral circuit transistors 210 may be disposed on the substrate 200. The plurality of peripheral circuit transistors 210 may include a sensing transistor, a transmission transistor, a driving transistor, etc. The plurality of peripheral circuit transistors 210 may configure, for example, a row decoder, a column decoder, a sense amplifier, a sub word line driver, etc. of the DRAM. However, embodiments are not limited to the above.

The wiring structure 220 may be disposed on the plurality of peripheral circuit transistors 210. The wiring structure 220 may be provided as an electrical connection path between the plurality of peripheral circuit transistors 210 and the cell structure CELL.

The cell structure CELL may be disposed on the peripheral circuit structure PERI. The peripheral circuit structure PERI and the cell structure CELL may be bonded to each other. For example, the first bonding insulating layer 101 of the cell structure CELL and the second bonding insulating layer 201 of the peripheral circuit structure PERI may be bonded to each other. A chemical bond may be formed between the constituent material of the first bonding insulating layer 101 and the constituent material of the second bonding insulating layer 201.

Each of the first bonding insulating layer 101 and the second bonding insulating layer 201 may include one of, for example, silicon carbonitride (SiCN), silicon nitride (SiN), silicon oxide carbonate (SiOC), silicon oxynitride (SiON), and silicon carbonate nitride (SiOCN).

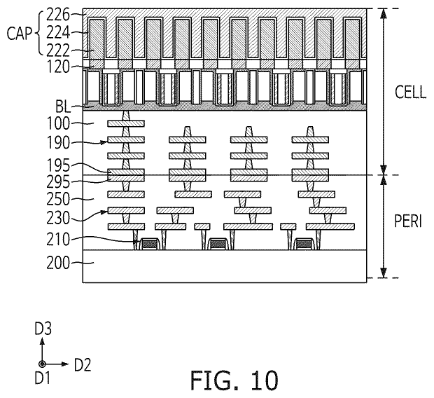

FIG. 10 is a diagram illustrating a semiconductor memory device according to some embodiments. For convenience of explanation, different configurations from those described in FIGS. 1 to 9 will be mainly described.

Referring to FIG. 10, the semiconductor memory device according to some embodiments may include a cell structure CELL and a peripheral circuit structure PERI.

The cell structure CELL may include a semiconductor memory device in a structure rotated by 180 degrees from FIGS. 1 to 8, the insulating substrate 100, and a first wiring structure 190 disposed in the insulating substrate 100. The information storage structure CAP may include the first electrode 222, the dielectric film 224, and the second electrode 226. Descriptions of the first electrode 222, the dielectric film 224, and the second electrode 226 may be similar to those described with reference to FIG. 9.

The insulating substrate 100 may be disposed below the bit line BL. The insulating substrate 100 may include an insulating material. The first wiring structure 190 may be disposed in the insulating substrate 100.

The first wiring structure 190 may be electrically connected to the peripheral circuit structure PERI. The first wiring structure 190 may include a first bonding pad 195. The first bonding pad 195 may be the pad of the first wiring structure 190, which is disposed closest to the peripheral circuit structure PERI. The first bonding pad 195 may be disposed on the lower surface of the insulating substrate 100.

The peripheral circuit structure PERI may include the substrate 200, the plurality of peripheral circuit transistors 210, a second wiring structure 230, and the peripheral circuit insulating film 250. The description of the substrate 200 and the plurality of peripheral circuit transistors 210 may be similar to that described with reference to FIG. 9.

The second wiring structure 230 may be disposed on the plurality of peripheral circuit transistors 210. The second wiring structure 230 may be provided as an electrical connection path between the plurality of peripheral circuit transistors 210 and the cell structure CELL.

The second wiring structure 230 may include a second bonding pad 295. The second bonding pad 295 may be a pad of the second wiring structures 230, which is disposed closest to the cell structure CELL. The first bonding pad 195 may be disposed on the second bonding pad 295. The first bonding pad 195 and the second bonding pad 295 may be metallically bonded to each other. For example, the first bonding pad 195 and the second bonding pad 295 may be coupled by Cu—Cu bonding. However, embodiments are not limited to the above. For example, each of the first bonding pad 195 and the second bonding pad 295 may include one of copper (Cu), tungsten (W), aluminum (Al), cobalt (Co), and molybdenum (Mo).

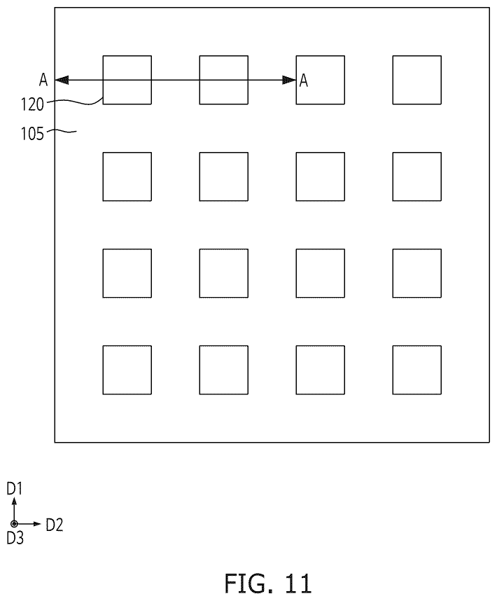

FIGS. 11 to 41 are diagrams illustrating intermediate stages, illustrating a method for manufacturing a semiconductor memory device according to some embodiments. For convenience of description, the same configuration as the configuration described with reference to FIGS. 1 to 5 will be briefly described or will not be described.

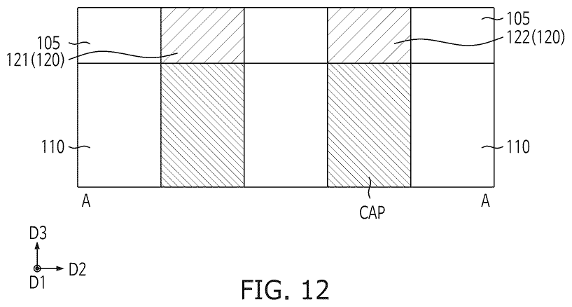

FIG. 11 is a plan view illustrating a method for manufacturing the semiconductor memory device according to some embodiments, and FIG. 12 is a cross-sectional view taken along line A-A of FIG. 11.

Referring to FIGS. 11 and 12, the plurality of conductive pads 120 and the second lower insulating film 105 surrounding the plurality of conductive pads 120 may be provided. The plurality of conductive pads 120 may be disposed on the information storage structure CAP. The conductive pads 120 may be disposed to be spaced apart from each other in the first and second directions D1 and D2. In some embodiments, the conductive pads 120 may be aligned in the first and second directions D1 and D2. The second lower insulating film 105 may be disposed on the first lower insulating film 110.

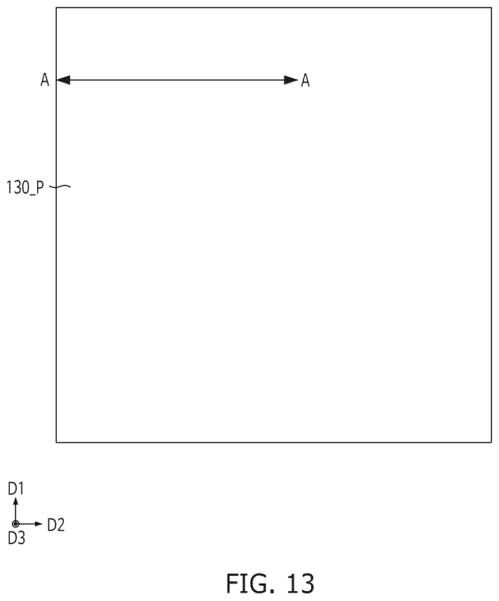

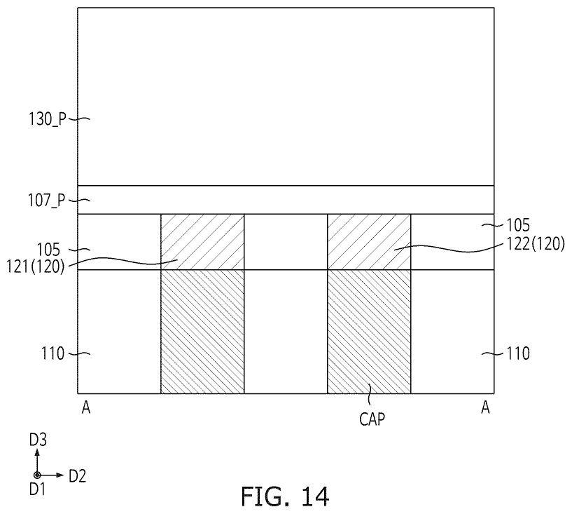

FIG. 13 is a plan view illustrating a method for manufacturing the semiconductor memory device according to some embodiments, and FIG. 14 is a cross-sectional view taken along line A-A of FIG. 13.

Referring to FIGS. 13 and 14, a pre insulating film 107_P and a pre mold pattern 130_P may be formed on the plurality of conductive pads 120 and the second lower insulating film 105.

The pre insulating film 107_P may be disposed on the plurality of conductive pads 120 and the second lower insulating film 105. The pre insulating film 107_P may cover upper surfaces of the plurality of conductive pads 120 and the upper surface of the second lower insulating film 105. The pre insulating film 107_P may include any one of, for example, silicon nitride, silicon oxynitride, silicon oxycarbonitride, and silicon carbonitride, and embodiments are not limited thereto.

The pre mold pattern 130_P may be disposed on the pre insulating film 107_P. The pre mold pattern 130_P may cover an upper surface of the pre insulating film 107_P. The pre mold pattern 130_P may include at least one of, for example, silicon oxide, silicon nitride, silicon oxynitride, and a low-k insulating material, and embodiments are not limited thereto.

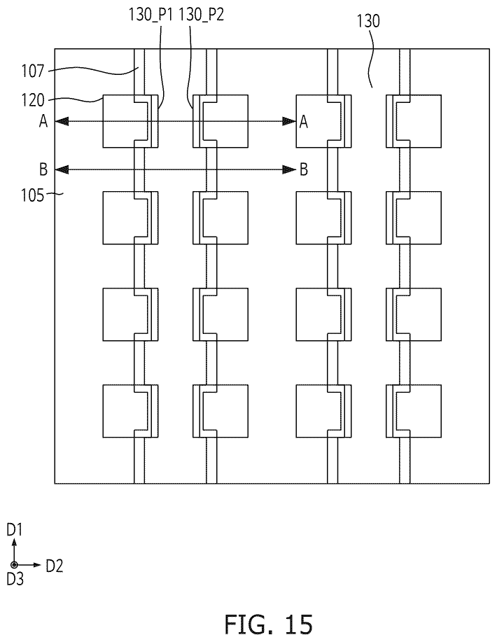

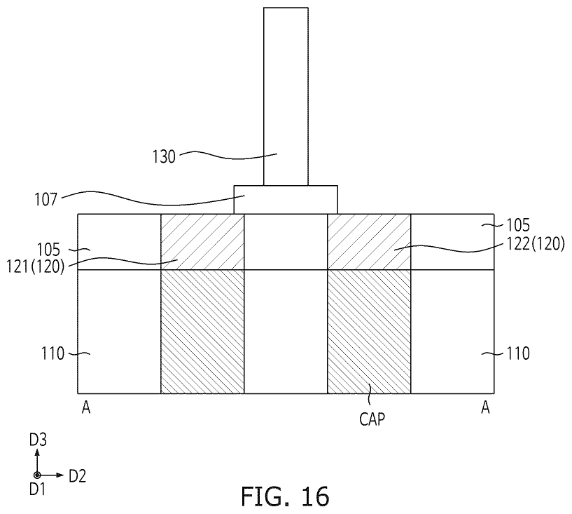

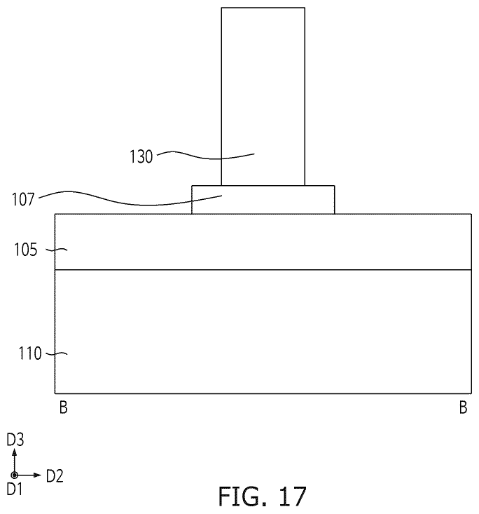

FIG. 15 is a plan view illustrating a method for manufacturing a semiconductor memory device according to some embodiments, and FIGS. 16 and 17 are cross-sectional views taken along line A-A and line B-B of FIG. 15.

Referring to FIGS. 15 to 17, a portion of the pre mold pattern 130_P of FIG. 14 may be removed to form the mold pattern 130, and a portion of the pre insulating film 107_P may be removed to form the protruding insulating film 107.

Specifically, the pre mold pattern 130_P may be patterned to form the mold pattern 130. The process of forming the mold pattern 130 may include an etching process using a photomask. For example, the first recessed part 130_P1 and the second recessed part 130_P2 of the mold pattern 130 may be formed by the etching process.

The mold pattern 130 may extend in the first direction D1. The mold pattern 130 may include the first recessed part 130_P1 and the second recessed part 130_P2. The first recessed part 130_P1 and the second recessed part 130_P2 may be spaced apart from each other in the second direction D2. Each of the first recessed part 130_P1 and the second recessed part 130_P2 may be recessed in opposite directions.

A portion of the pre insulating film 107_P may be removed to form the protruding insulating film 107. The protruding insulating film 107 may be disposed on the second lower insulating film 105. In some embodiments, a boundary surface between the protruding insulating film 107 and the second lower insulating film 105 may not be distinguished. However, embodiments are not limited to the above.

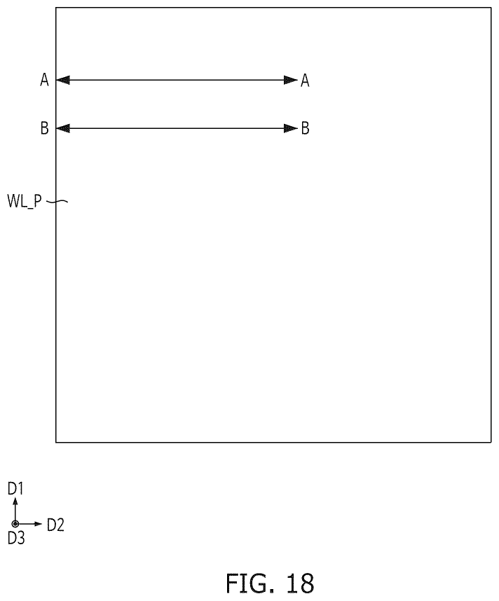

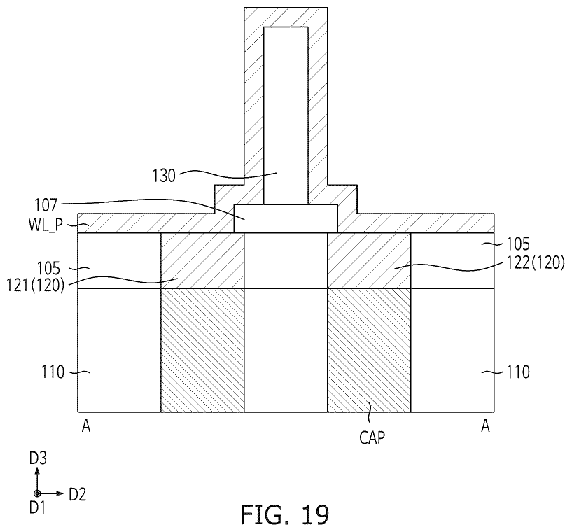

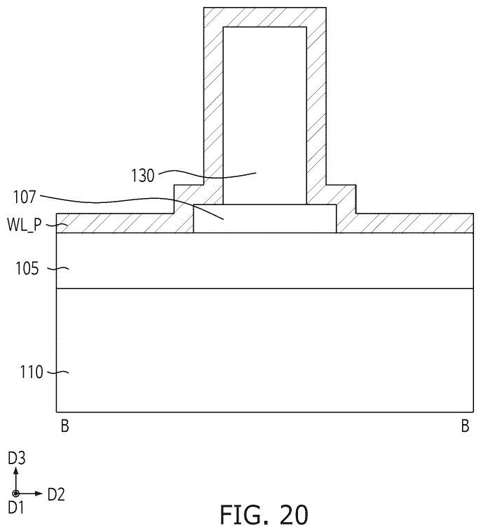

FIG. 18 is a plan view illustrating a method for manufacturing a semiconductor memory device according to some embodiments, and FIGS. 19 and 20 are cross-sectional views taken along line A-A and line B-B of FIG. 18.

Referring to FIGS. 18 to 20, a pre word line WL_P may be formed on the second lower insulating film 105, the plurality of conductive pads 120, the protruding insulating film 107, and the mold pattern 130.

The pre word line WL_P may extend along a profile of the mold pattern 130. For example, the pre word line WL_P may cover the side surface and the upper surface of the mold pattern 130. For example, the word line WL_P may be formed by any one of Physical Vapor Deposition (PVD) method and Chemical Vapor Deposition (CVD) method. However, embodiments are not limited to the above.

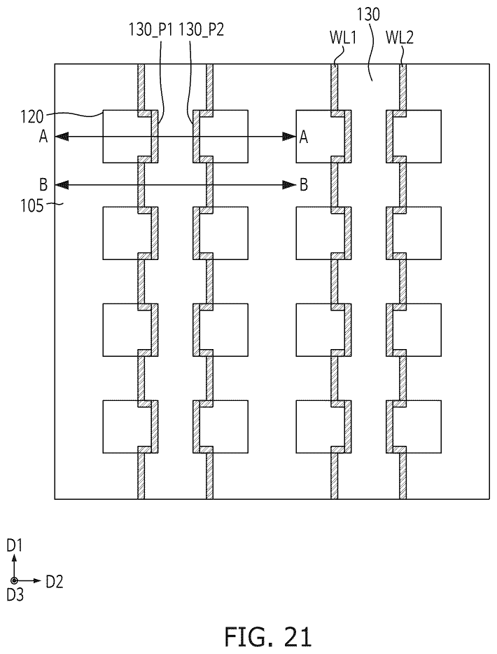

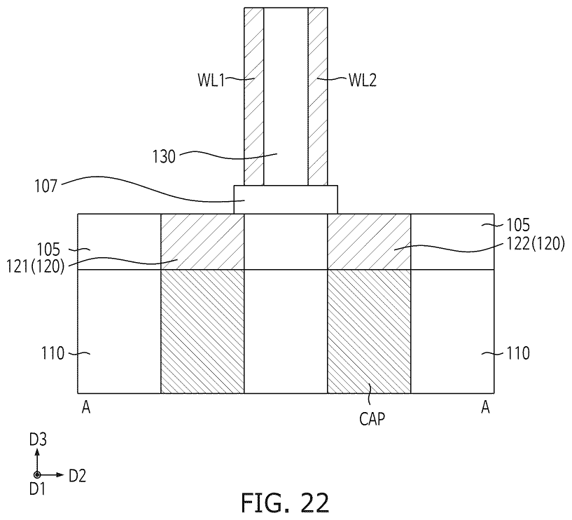

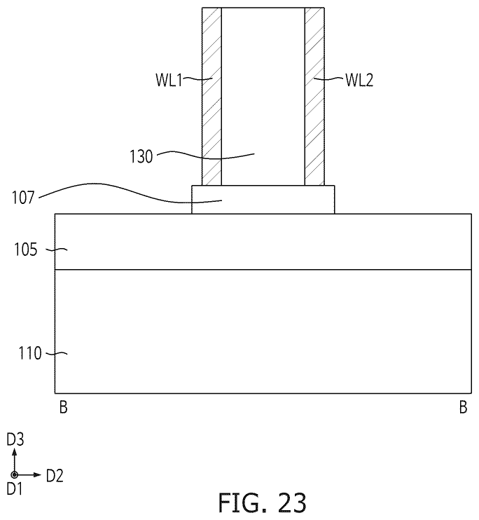

FIG. 21 is a plan view illustrating a method for manufacturing a semiconductor memory device according to some embodiments, and FIGS. 22 and 23 are cross-sectional views taken along line A-A and line B-B of FIG. 21. For reference, the protruding insulating film 107 is omitted from FIG. 21.

Referring to FIGS. 21 to 23, the first word line WL1 and the second word line WL2 may be formed on both sides of the mold pattern 130.

Specifically, a portion of the pre word line WL_P of FIG. 19 may be removed by the etching process. The first word line WL1 and the second word line WL2 may be formed by the etching process. The first word line WL1 may extend in the first direction D1 along one side surface of the mold pattern 130, and the second word line WL2 may extend in the first direction D1 along the other side surface of the mold pattern 130. A portion of the pre word line WL_P may be removed to expose the upper surface of the mold pattern 130, the upper surfaces of the plurality of conductive pads 120, and the upper surface of the second lower insulating film 105.

The first word line WL1 may extend along the first recessed part 130_P1 of the mold pattern 130, and the second word line WL2 may extend along the second recessed part 130_P2 of the mold pattern 130. The distance between the first word line WL1 and the second word line WL2 spaced apart from the first word line WL1 in the second direction D2 may not be constant. The distance between the first word line WL1 and the second word line WL2 spaced apart from the first word line WL1 in FIG. 22 may be less than the distance between the first word line WL1 and the second word line WL2 spaced apart from the first word line WL1 in FIG. 23.

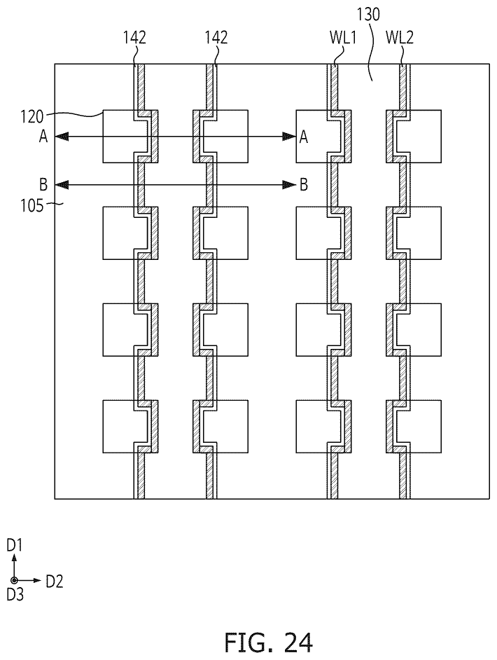

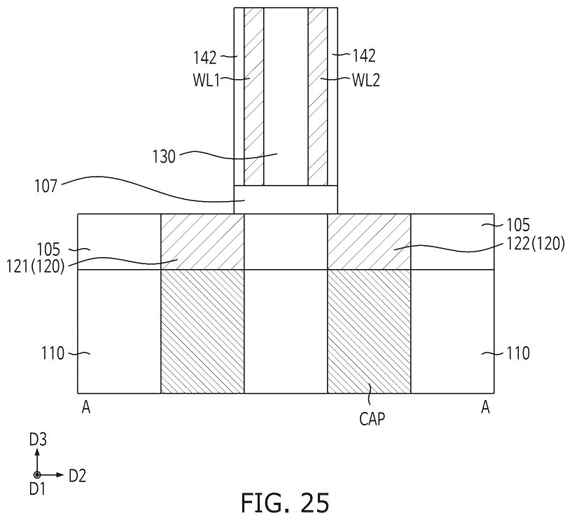

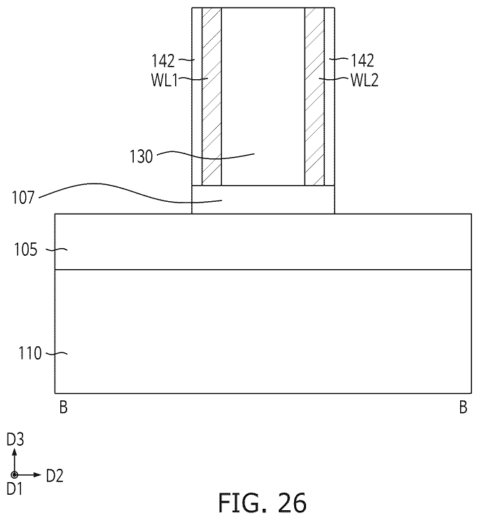

FIG. 24 is a plan view illustrating a method for manufacturing a semiconductor memory device according to some embodiments, and FIGS. 25 and 26 are cross-sectional views taken along line A-A and line B-B of FIG. 24. For reference, the protruding insulating film 107 is omitted from FIG. 24.

Referring to FIGS. 24 to 26, a first liner film 142 may be formed on the first word line WL1 and the second word line WL2. The first liner film 142 may be disposed on a side surface of the first word line WL1 and a side surface of the second word line WL2.

In some embodiments, a pre liner film may be formed to cover the second lower insulating film 105, the plurality of conductive pads 120, the first word line WL1, the second word line WL2, and the mold pattern 130. A portion of the pre liner film may be removed by an etching process to form the first liner film 142. The first liner film may include, for example, at least one of silicon oxide, silicon oxynitride, and a high-k material with a higher dielectric constant than silicon oxide. The high-k material may include a metal oxide or a metal oxynitride. For example, the high-k material of the liner insulating film 140 may include at least one of HfO₂, HfSiO, HfSiON, HfTaO, HfTiO, HfZrO, ZrO₂ and Al₂O₃, but embodiments are not limited thereto.

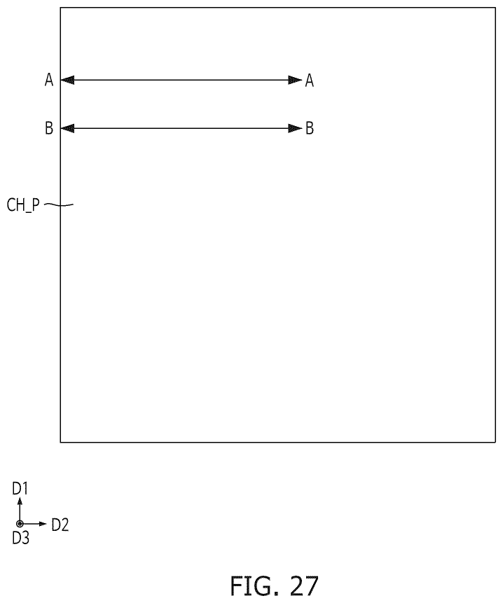

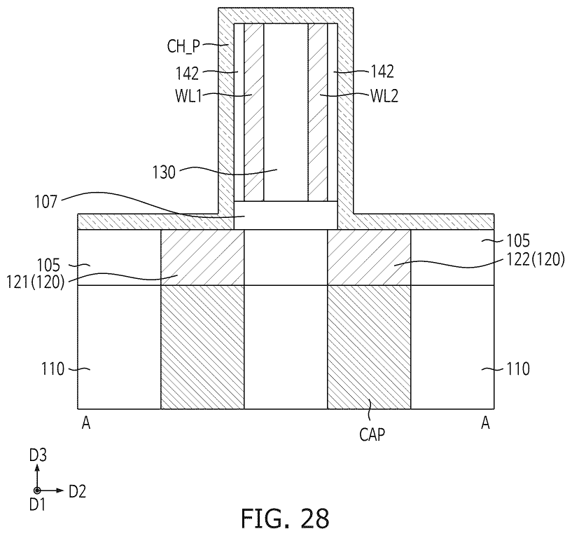

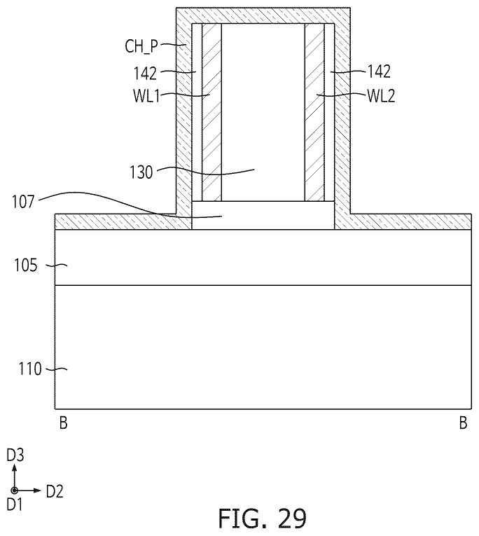

FIG. 27 is a plan view illustrating a method for manufacturing a semiconductor memory device according to some embodiments, and FIGS. 28 and 29 are cross-sectional views taken along line A-A and line B-B of FIG. 27.

Referring to FIGS. 27 to 29, a pre channel layer CH_P may be formed on the first liner film 142.

Specifically, the pre channel layer CH_P may be disposed on the second lower insulating film 105, the plurality of conductive pads 120, side and upper surfaces of the first liner film 142, the upper surface of the first word line WL1, the upper surface of the mold pattern 130, and the upper surface of the second word line WL2. The pre channel layer CH_P may be formed along a profile of the side surface of the first word line WL1, and may be formed along a profile of the side surface of the second word line WL2. That is, along the word lines WL1 and WL2, a width of the pre channel layer CH_P in the second direction D2 may vary as illustrated in FIGS. 28 and 29.

Description of the material of the pre channel layer CH_P may be the same as the description of the material of the first channel structure CH1 and the second channel structure CH2 described with reference to FIGS. 1 to 5.

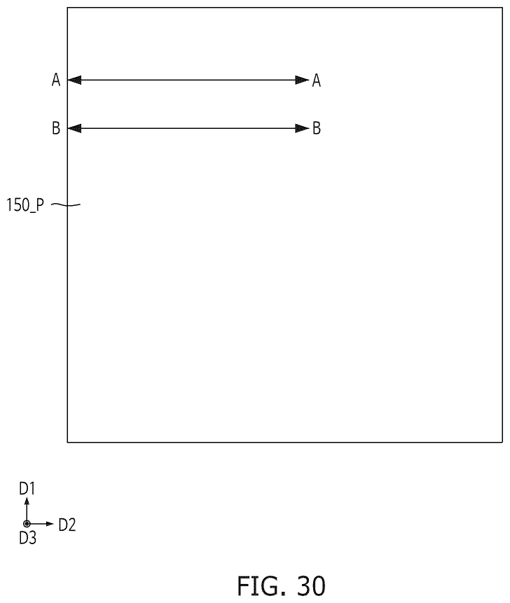

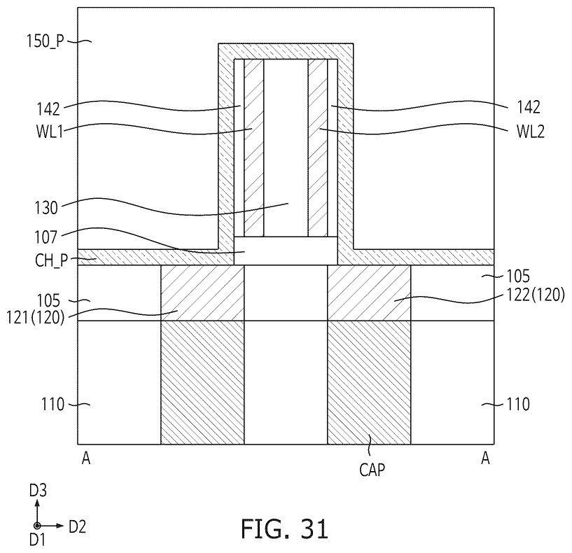

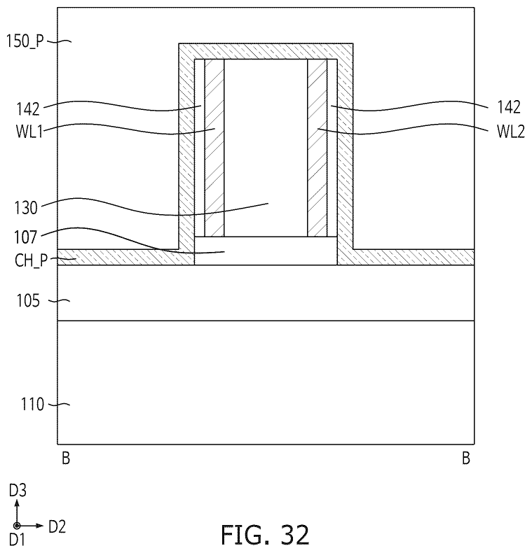

FIG. 30 is a plan view illustrating a method for manufacturing a semiconductor memory device according to some embodiments, and FIGS. 31 and 32 are cross-sectional views taken along line A-A and line B-B of FIG. 30.

Referring to FIGS. 30 to 32, a pre upper insulating film 150_P may be formed on the pre channel layer CH_P. The pre upper insulating film 150_P may cover the pre channel layer CH_P. For example, the pre upper insulating film 150_P may include at least one of silicon oxide, silicon oxynitride, and a low-k material having a lower dielectric constant than silicon oxide, but embodiments are not limited thereto.

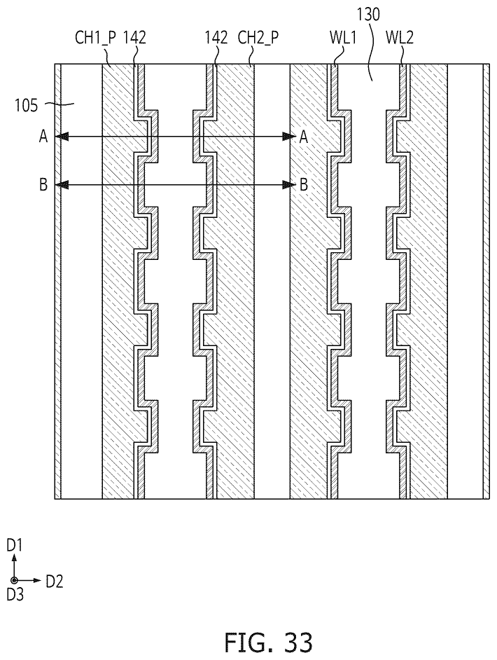

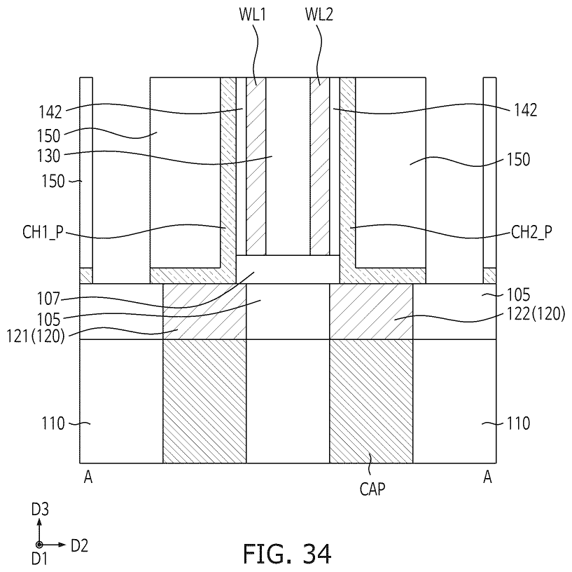

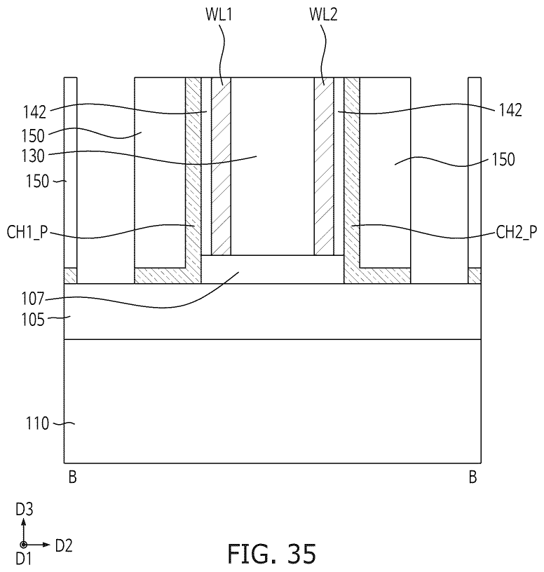

FIG. 33 is a plan view illustrating a method for manufacturing a semiconductor memory device according to some embodiments, and FIGS. 34 and 35 are cross-sectional views taken along line A-A and line B-B of FIG. 33. For reference, the upper insulating film 150 is omitted from FIG. 33.

Referring to FIGS. 33 to 35, a portion of the pre upper insulating film 150_P of FIG. 31 and a portion of the pre channel layer CH_P may be removed to form the upper insulating film 150, a pre first channel CH1_P, and a pre second channel CH2_P.

Specifically, a first mask pattern may be formed on the pre upper insulating film 150_P. The first mask pattern may include an opening that exposes a portion of the pre upper insulating film 150_P. The opening of the first mask pattern may extend in the first direction D1. Portions of the pre upper insulating film 150_P and the pre channel layer CH_P may be removed by using the first mask pattern as an etching mask. As a result, the pre first channel CH1_P, the pre second channel CH2_P, and the upper insulating film 150 may be formed. The pre first channel CH1_P and the pre second channel CH2_P may extend in the first direction D1.

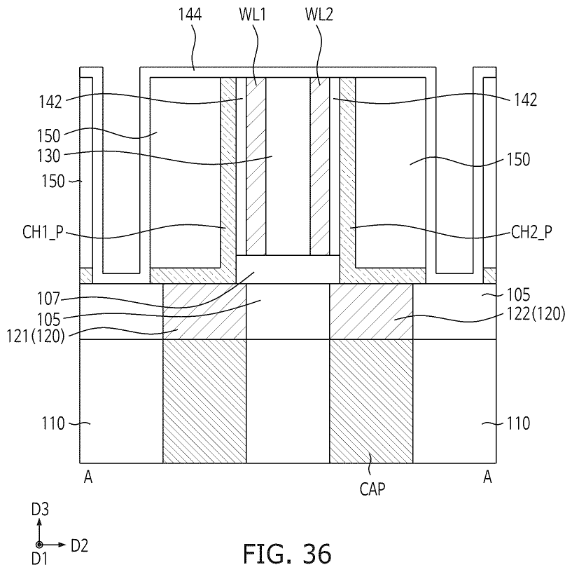

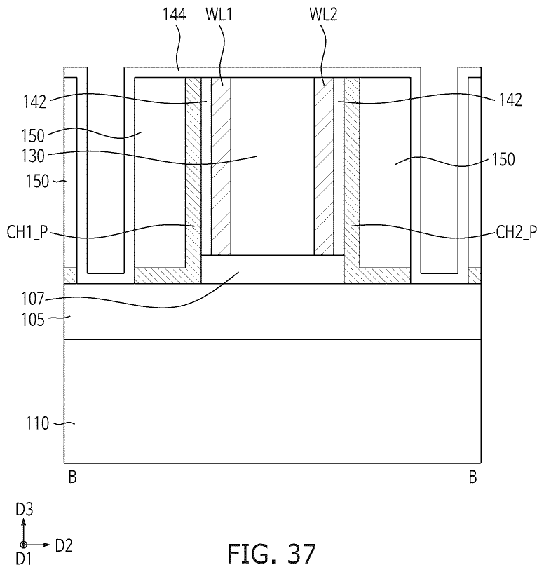

FIGS. 36 and 37 are diagrams illustrating a method for manufacturing a semiconductor memory device according to some embodiments. FIG. 36 may correspond to a cross-sectional view taken along line A-A of FIG. 33, and FIG. 37 may correspond to a cross-sectional view taken along line B-B of FIG. 33.

Referring to FIGS. 36 and 37, a second liner film 144 may be formed on the upper insulating film 150, the second lower insulating film 105, the pre first channel CH1_P, the pre second channel CH2_P, the first word line WL1, the second word line WL2, and the mold pattern 130.

The second liner film 144 may be disposed on the upper surface and the side surface of the upper insulating film 150. The second liner film 144 may be disposed between the upper insulating film 150 and an adjacent upper insulating film 150 in the second direction D2. In some embodiments, the second liner film 144 may be conformally formed.

The description of the material of the second liner film 144 may be the same as the description of the material of the first liner film 142. In some embodiments, the first liner film 142 and the second liner film 144 may include the same material. In this case, a boundary surface between the first liner film 142 and the second liner film 144 may not be distinguished.

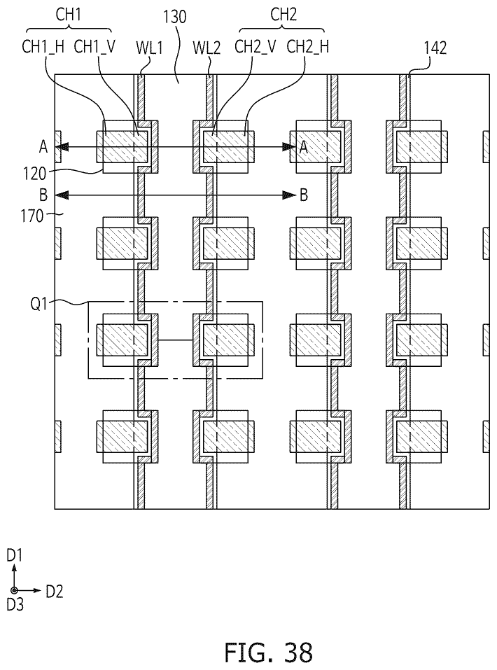

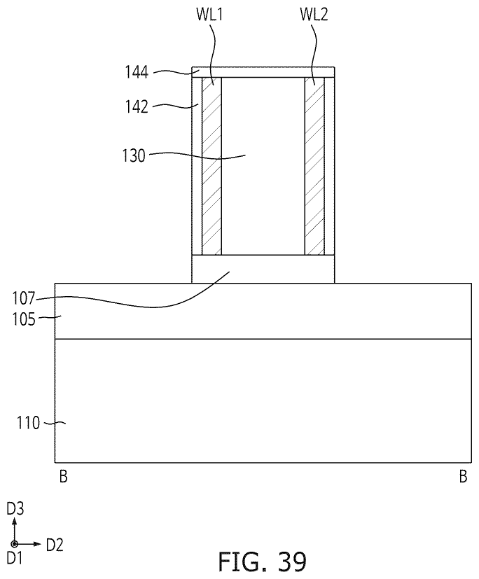

FIG. 38 is a plan view illustrating a method for manufacturing a semiconductor memory device according to some embodiments, and FIG. 39 is a cross-sectional view taken along line B-B in FIG. 38. For reference, a cross-sectional view along line A-A of FIG. 38 may be identical to FIG. 36.

Referring to FIGS. 38 and 39, a portion of the upper insulating film 150, a portion of the pre first channel CH1_P of FIG. 36, and the pre second channel CH2_P of FIG. 36 may be removed to form the first channel structure CH1 and the second channel structure CH2.

Specifically, a second mask pattern may be formed on the upper insulating film 150. The second mask pattern may include an opening extending in the second direction D2. The opening of the second mask pattern may expose a portion of the upper insulating film 150. A portion of the upper insulating film 150, a portion of the pre first channel CH1_P, and the pre second channel CH2_P may be removed by using the second mask pattern as an etching mask. In this case, a portion of the second liner film 144 may also be removed. For example, the second liner film 144 disposed on the second lower insulating film 105 as illustrated in FIG. 39 may be removed.

As a result, the first channel structure CH1 and the second channel structure CH2 may be formed. The first channel structure CH1 and the second channel structure CH2 may be disposed to be spaced apart from each other in the second direction D2. The first channel structures CH1 may be aligned at intervals from each other in the first direction D1, and the second channel structures CH2 may be aligned at intervals from each other in the first direction D1. The first channel structure CH1 may include the first horizontal portion CH1_H and the first vertical portion CH1_V. The second channel structure CH2 may include the second horizontal portion CH2_H and the second vertical portion CH2_V.

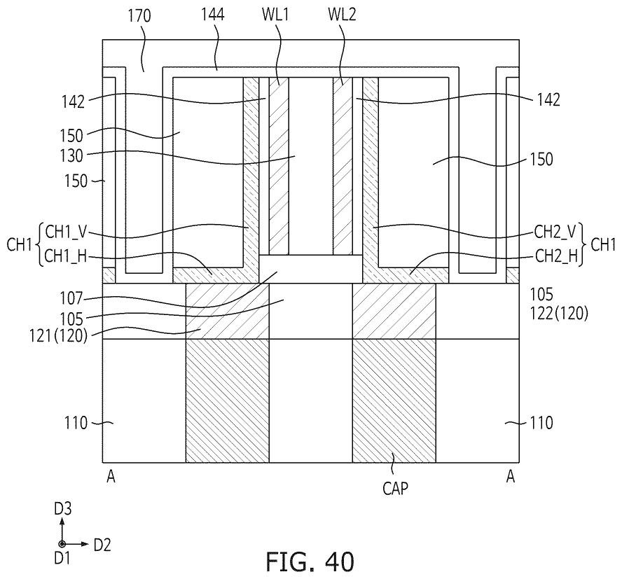

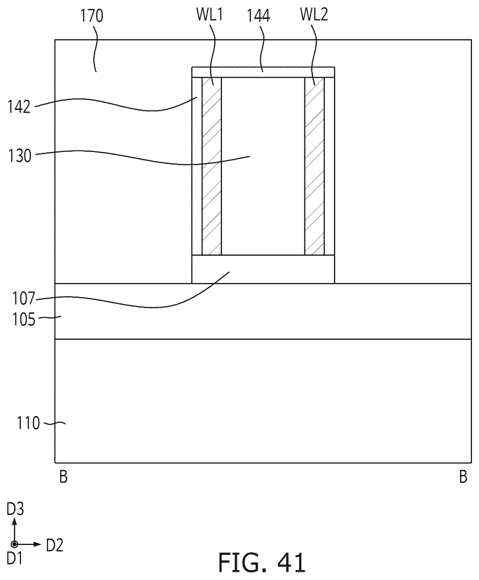

FIGS. 40 and 41 are diagrams illustrating a method for manufacturing a semiconductor memory device according to some embodiments. FIG. 40 may correspond to a cross-sectional view taken along line A-A of FIG. 38, and FIG. 41 may correspond to a cross-sectional view taken along line B-B of FIG. 38.

Referring to FIGS. 40 and 41, the interlayer insulating film 170 may be formed on the second liner film 144. The interlayer insulating film 170 may cover the second liner film 144 and the second lower insulating film 105. The interlayer insulating film 170 may fill a space between upper insulating films 150.

The interlayer insulating film 170 may be patterned. For example, a trench extending in the second direction D2 may be formed on the interlayer insulating film 170. The trench may expose the upper surface of the first vertical portion CH1_V and the upper surface of the second vertical portion CH2_V. A conductive material may be deposited inside the trench to form a bit line (BL in FIG. 2).

Although certain embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects.

1. A semiconductor memory device, comprising:
a conductive pad on an information storage structure;
a channel structure on the conductive pad and comprising a vertical portion extending in a first direction;
a word line extending in a second direction and on a plurality of side surfaces of the vertical portion, wherein the second direction is substantially perpendicular to the first direction; and
a bit line on the channel structure and extending in a third direction intersecting with the second direction, wherein the third direction is substantially perpendicular to the first direction.

2. The semiconductor memory device according to claim 1, wherein
the plurality of side surfaces of the vertical portion of the channel structure comprises a first side surface, a second side surface connected to the first side surface, and a third side surface connected to the second side surface and opposite the first side surface, and
the word line is on the first side surface, the second side surface, and the third side surface.

3. The semiconductor memory device according to claim 1, wherein
the channel structure further comprises a horizontal portion disposed on the conductive pad and extending in the third direction, and
the vertical portion of the channel structure extends in the first direction on the horizontal portion.

4. The semiconductor memory device according to claim 3, wherein the horizontal portion of the channel structure overlaps with at least a portion of an upper surface of the conductive pad in the first direction.

5. The semiconductor memory device according to claim 1, wherein the word line comprises an extended part extending in the second direction and a recessed part adjacent to the plurality of side surfaces of the vertical portion of the channel structure.

6. The semiconductor memory device according to claim 1, wherein a width of the conductive pad in the second direction is equal to or greater than a width of the channel structure in the second direction.

7. The semiconductor memory device according to claim 1, further comprising:
a liner insulating film extending along the word line in the second direction and between the word line and the channel structure.

8. The semiconductor memory device according to claim 1, further comprising:
an upper insulating film between the channel structure and the bit line.

9. The semiconductor memory device according to claim 1, wherein the bit line is in contact with a surface of the vertical portion opposite the conductive pad and a portion of the side surfaces of the vertical portion.

10. The semiconductor memory device according to claim 1, wherein a surface of the vertical portion opposite the conductive pad is coplanar with a surface of the word line opposite the conductive pad.

11. A semiconductor memory device, comprising:
first and second conductive pads on an information storage structure, respectively;
a first channel structure on the first conductive pad and extending in a first direction;
a second channel structure on the second conductive pad and extending in the first direction;
a first word line extending in a second direction and on one side of the first channel structure, wherein the second direction is substantially perpendicular to the first direction;
a second word line extending in the second direction, spaced apart from the first word line in a third direction intersecting with the second direction and substantially perpendicular to the first direction, and on one side of the second channel structure;
a mold pattern between the first word line and the second word line;
a liner insulating film between the first word line and the first channel structure and between the second word line and the second channel structure; and
a bit line extending in the third direction and on a surface of the first channel structure opposite the first conductive pad and a surface of the second channel structure opposite the second conductive pad, wherein
the first word line is adjacent to at least a portion of a side surface of the first channel structure, and
the second word line is adjacent to at least a portion of a side surface of the second channel structure.

12. The semiconductor memory device according to claim 11, wherein
the mold pattern extends in the second direction, and
a width of the mold pattern in the third direction varies.

13. The semiconductor memory device according to claim 11, wherein
the mold pattern comprises a first recessed part and a second recessed part spaced apart from the first recessed part in the third direction,
the first recessed part overlaps with the first channel structure in the third direction, and
the second recessed part overlaps with the second channel structure in the third direction.

14. The semiconductor memory device according to claim 13, wherein
the first word line extends along the first recessed part of the mold pattern, and
the second word line extends along the second recessed part of the mold pattern.

15. The semiconductor memory device according to claim 11, wherein
the first channel structure is spaced apart from the second channel structure in the third direction, and
each of the first word line and the second word line is between the first channel structure and the second channel structure.

16. The semiconductor memory device according to claim 11, further comprising:
a lower insulating film on the first conductive pad and the second conductive pad; and
a protruding insulating film between the lower insulating film and the mold pattern.

17. The semiconductor memory device according to claim 16, wherein a width of the protruding insulating film in the third direction is greater than a width of the mold pattern in the third direction.

18. The semiconductor memory device according to claim 11, wherein a distance between the first conductive pad and the second conductive pad in the third direction is equal to or greater than a width of the first conductive pad in the third direction.

19. The semiconductor memory device according to claim 11, wherein
the first channel structure comprises a first horizontal portion on a surface of the first conductive pad, and a first vertical portion on the first horizontal portion and extending in the first direction, and
the second channel structure comprises a second horizontal portion on a surface of the second conductive pad, and a second vertical portion on the second horizontal portion and extending in the first direction.

20. A semiconductor memory device, comprising:
first and second conductive pads on respective information storage structures;
a lower insulating film on the first conductive pad and the second conductive pad;
a first channel structure comprising a first horizontal portion on the first conductive pad and extending in a first direction, and a first vertical portion extending in a second direction on the first horizontal portion, wherein the second direction is substantially perpendicular to the first direction;
a second channel structure comprising a second horizontal portion on the second conductive pad and extending in the first direction, and a second vertical portion extending in the second direction on the second horizontal portion;
a first word line extending in a third direction intersecting with the first direction and on one side of the first vertical portion;
a second word line extending in the third direction and on one side of the second vertical portion;
a mold pattern between the first word line and the second word line;
a liner insulating film between the first word line and the first channel structure and between the second word line and the second channel structure; and
a bit line extending in the first direction and on a surface of the first channel structure opposite the first conductive pad and a surface of the second channel structure opposite the second conductive pad, wherein
the first word line is on a first side surface, a second side surface, and a third side surface of the first vertical portion, and
the first side surface and the third side surface of the first vertical portion oppose each other in the third direction and are each connected to the second side surface.
